(19) United States
(12) Patent Application Publication
(10) Pub. No.: US 2009/0032827 A1
(43) Pub. Date: Feb. 5, 2009

(54) Concave Wide Emitting Lens for LED Useful for Backlighting

(75) Inventor: Willem H. Smits, Veldhoven (NL)

Correspondence Address: PATENT LAW GROUP LLP, 2635 NORTH FIRST STREET, SUITE 223, SAN JOSE, CA, 95134, US

(73) Assignee: PHILIPS LUMILEDS LIGHTING COMPANY, LLC, San Jose, CA (US)

(21) Appl. No.: 11/830,564

(22) Filed: Jul. 30, 2007

(51) Int. Cl. H01L 33/00

(52) U.S. Cl. 257/89; 257/98; 257/E33.059

(57) ABSTRACT

Lenses for LEDs are described that efficiently create a substantially uniform light emission across a surface of a backlight box. The backlight may illuminate an LCD. A wide-emitting lens refracts light emitted by an LED die to cause a peak intensity to occur within 35-65 degrees off the die's center axis, normal to the die's top surface, and an intensity along the center axis to be between 40% and 90% of the peak intensity. The lens is concave over the die and has smooth edges that transition into the lens sidewalls. The direct emissions of the lenses from a plurality of LEDs arranged on a base surface in a backlight box combine together to uniformly illuminate a light output surface of the backlight box.

### FIELD OF THE INVENTION

This invention relates to light emitting diodes (LEDs) and, in particular, to certain lens designs useful for backlighting.

### BACKGROUND

LED dies typically emit light in a lambertian pattern. It is common to use a lens over the LED die to narrow the beam or to make a side-emission pattern. A common type of lens for a surface mounted LED is preformed molded plastic, which is bonded to a package in which the LED die is mounted. One such lens is shown in U.S. Pat. No. 6,274,924, assigned to Philips Lumileds Lighting Company and incorporated herein by reference.

When LEDs are the light source in a backlight, various techniques have been used to prevent the small LED die from appearing as a bright dot on the backlight's output surface. For example, for small backlights, LEDs may illuminate a solid, transparent light guide from the side edges. The LED light then mixes in the light guide and leaks out the top with a uniform emission profile. In larger backlights, designed by the present assignee, the LEDs are distributed on the base surface of a reflective backlight box, and each LED has a side emitting lens that greatly limits the light emission normal to the LED. The side emissions are mixed in the box and eventually leak out through the top opening of the box to create a uniform emission profile. In such a backlight, the reflected and mixed sidelight constitutes a vast majority of the light ultimately emitted by the backlight. It is inherent in such a design that light is attenuated by each reflection.

The present assignee has developed an overmolding technique that molds a lens directly over the LED in virtually any shape. Various backlights using side-emitting lenses formed by overmolding are described in U.S. application publication number US 2006/0102914, assigned to Philips Lumileds Lighting Company and incorporated herein by reference.

### SUMMARY

A new lens surface shape is disclosed for an LED, where the lens is concave over the LED die, and the rim of the concave portion smoothly transitions into the sidewalls. The rim is at a particular radius from the center line to achieve the desired emission pattern. The shape of the lens results in a maximum intensity between 35-65 degrees with respect to the normal of the LED die surface. Instead of minimizing the emission at the normal of the LED, as is typically done with side-emitting lenses, the intensity along the normal is 40-90% of the maximum intensity.

The lens is preferably silicone and formed by molding directly over the LED die.

One or more of the LEDs incorporating the lens are used in a reflective backlight box, where the light emission from the lens directly illuminates a light emitting surface of the backlight (e.g., a diffuser sheet or a brightness enhancement film) and exits the backlight. Although there will be some reflected light inside the backlight box (reflected off the backlight box walls), such reflected light does not form the majority of the light that ultimately exits the backlight. In one embodiment, at least 50% of the light exiting the backlight box is from direct illumination by the LEDs.

The LEDs in the backlight box may be blue, red, and green LEDs, or use phosphor conversion to create red, green, and blue light components. The optimum lens shape for each type of LED may be different to achieve the desired brightness profile.

The thickness of the lens, the width of the lens, the shape of the lens, and the distance between the top of the lens and the top surface of the backlight are optimized to maximize the efficiency and brightness uniformity of the backlight.

### BRIEF DESCRIPTION OF THE DRAWINGS

FIG. 1 is a cross-sectional view of a shaped LED die mounted on a submount, where the lens of the present invention is molded over the LED die.

FIG. 2 is a cross-sectional view of an ultra-thin LED die mounted on a submount, where the lens of the present invention is molded over the LED die.

FIGS. 3A and 3B illustrate the emission pattern of the LED due to the lens shape.

FIG. 4 is a cross-sectional view of a backlight incorporating an array of encapsulated LEDs similar to FIG. 1 or FIG. 2.

FIG. 5A is a top down view of a simple backlight housing four LEDs having circular lenses, showing overlapping equi-brightness circular emission patterns resulting from the lenses.

FIG. 5B is a top down view of an LED with a circular lens.

FIG. 6A is a top down view of a simple backlight housing four LEDs having rectangular lenses, showing equi-brightness rectangular emission patterns resulting from the lenses.

FIG. 6B is a top down view of an LED with a rectangular lens.

FIGS. 7 and 8 are detailed cross-sectional views of one type of flip-chip LED die encapsulated by the new lens, where phosphor is either dispersed in the lens material (FIG. 7) or located as a layer over the die (FIG. 8).

Elements labeled with the same numeral in the various figures may be the same or equivalent.

### DETAILED DESCRIPTION

As a preliminary matter, a conventional LED is formed on a growth substrate. In the example used, the LED is a GaN-based LED, such as an AlInGaN LED, for producing blue or UV light. Typically, a relatively thick n-type GaN layer is grown on a sapphire growth substrate using conventional techniques. The relatively thick GaN layer typically includes a low temperature nucleation layer and one or more additional layers so as to provide a low-defect lattice structure for the n-type cladding layer and active layer. One or more n-type cladding layers are then formed over the thick n-type layer, followed by an active layer, one or more p-type cladding layers, and a p-type contact layer (for metallization).

Various techniques are used to gain electrical access to the n-layers. In a flip-chip example, portions of the p-layers and active layer are etched away to expose an n-layer for metallization. In this way the p contact and n contact are on the same side of the chip and can be directly electrically attached to the package (or submount) contact pads. Current from the n-metal contact initially spreads laterally through the n-layer. In contrast, in a vertical injection (non-flip-chip) LED, an n-contact is formed on one side of the chip, and a p-contact is formed on the other side of the chip. Electrical contact to one of the p or n-contacts is typically made with a wire or a metal bridge, and the other contact is directly bonded to a package (or submount) contact pad. A flip-chip LED is used in the various examples for simplicity, although a non-flip-chip LED may be used instead.

Examples of forming LEDs are described in U.S. Pat. Nos. 6,649,440 and 6,274,399, both assigned to Philips Lumileds Lighting Company and incorporated herein by reference.

Optionally, the metal pads on the LED dice are bonded to pads on a submount wafer, and the sapphire substrate is removed. The submount wafer is then singulated by sawing to separate out the LEDs. Electrodes of one or more submounts may then be bonded to a printed circuit board, which contains metal leads for connection to other LEDs and to a power supply. The circuit board may interconnect various LEDs in series and/or parallel.

The particular LEDs formed and whether or not they are mounted on a submount is not important for purposes of understanding the invention.

In the preferred embodiment for forming a lens over each LED die, an array of LEDs is mounted on a submount wafer. The submount may be a ceramic substrate, a silicon substrate, or other type of support structure with the LED dice electrically connected to metal pads on the submount. A lens is then overmolded onto each LED die simultaneously using the overmolding process described in U.S. application publication number US 2006/0102914, assigned to Philips Lumileds Lighting Company.

In this overmolding process, a mold has indentations in it corresponding to the positions of the LED dice on the submount wafer. The indentations are filled with a liquid, optically transparent material, such as silicone, which when cured forms a hardened lens material. The shape of the indentations will be the shape of the lens. The mold and the LED dice/support structure are brought together so that each LED die resides within the liquid lens material in an associated indentation.

The mold is then heated to cure (harden) the lens material. The mold and the substrate wafer are then separated, leaving a complete lens over each LED die, completely encapsulating the die. This general process is referred to as overmolding. The submount wafer is then singulated to separate out the LEDs.

In one embodiment, the inventive lens is the only overmolded lens encapsulating the LED. In another embodiment, a hemispherical lens is first overmolded on the LED to encapsulate the LED, followed by molding the inventive lens over the hemispherical lens.

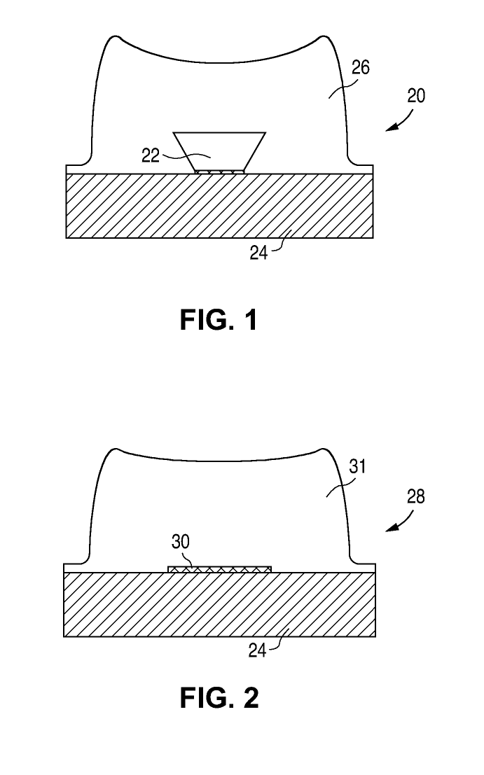

FIG. 1 is a cross-sectional view of an LED 20 comprising a semiconductor LED die 22 mounted to a submount 24 and encapsulated by an overmolded lens 26, in accordance with one embodiment of the invention. The die 22 is shaped to increase light extraction. Such chip shaping is described in U.S. Pat. No. 6,570,190, assigned to the present assignee and incorporated by reference.

The lens 26 has a concave shape above the die 22 and has a rounded rim at a certain radius, where the lens 26 is the thickest, then falls off. The sidewalls of the lens 26 are substantially vertical, such as at an angle of 10-15% with respect to vertical.

In one example, the surface of the lens 26 is described by the following equation, where Z is the vertical distance of the lens surface to the top of the LED die and R (radius) is the distance from the centerline. The dimensions are given relative to a center height of 1.0.

Z(R)=1.0+0.4*R⁴−0.0497*R¹⁴ eq. 1

FIG. 2 is a cross-sectional view of an LED 28 comprising an ultra-thin semiconductor LED die 30 mounted to a submount 24 and encapsulated by an overmolded lens 31, in accordance with one embodiment of the invention. The die 30 may be made very thin by removing the growth substrate. The concavity of the lens 31 is less than that of lens 26 since the LED die is wider and further from the lens surface. In one example, the surface of the lens 31 is described by the following equation:

Z(R)=1.0+0.2*R⁶−0.0921*R¹² eq. 2

Depending on the specific requirements for a radiation pattern, the values of the polynomial coefficients can be optimized. Therefore, the general polynomial function is:

Z(R)=C0+C2*R²+C4*R⁴+C6*R⁶+C8*R⁸+C10*R¹⁰+C12*R¹²+C14*R¹⁴ eq. 3

The lens curvature is not restricted to polynomial functions.

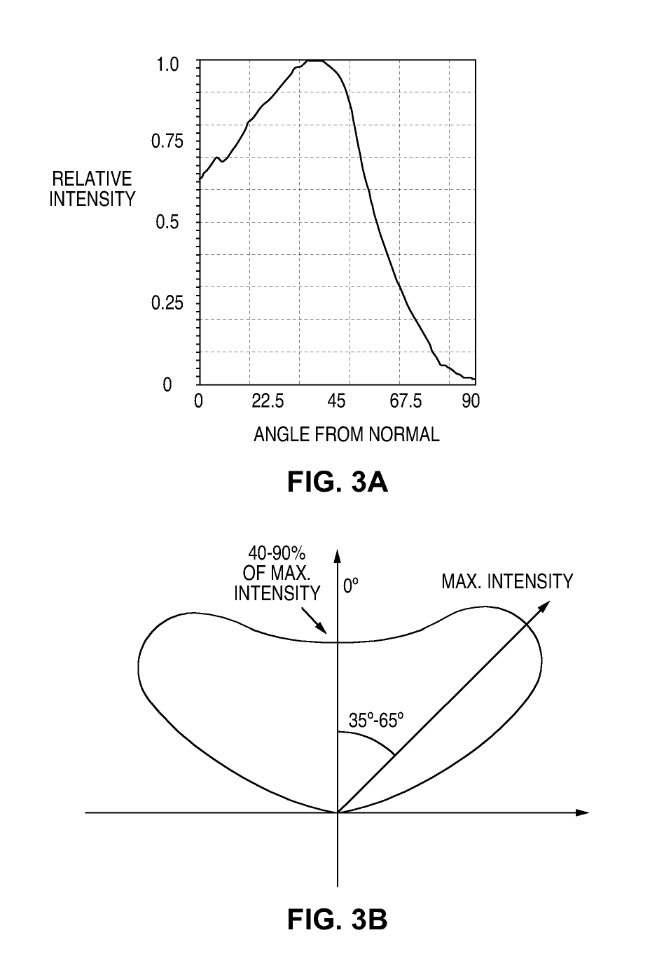

FIG. 3A is a graph of the relative intensity (lm/sr) versus the angle away from the normal of the LED die top surface. FIG. 3B illustrates the same emission pattern where the pattern represents equal intensity of the emission at various angles. The LED top surface, simplified to be a point source, is at the 0,0 point.

Since the light is broadly concentrated within a certain angle, the light pattern is about 1.5-2 times wider than a Lambertian pattern for the same brightness level contour.

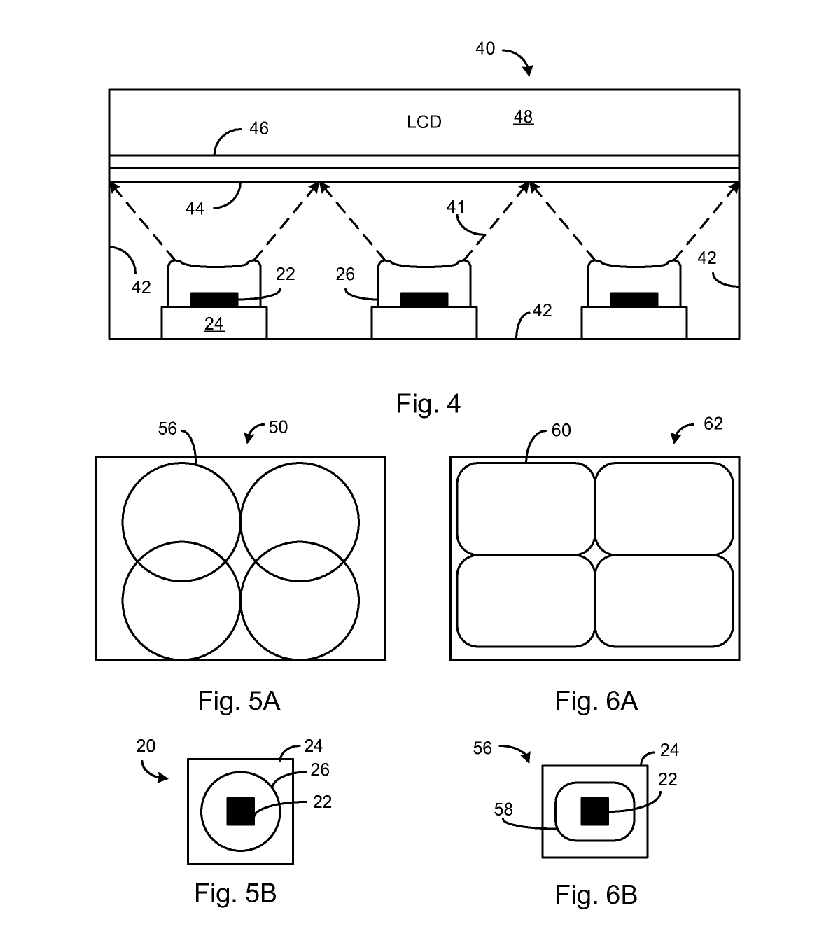

In the preferred embodiment, the peak intensity is between 35-65 degrees off the normal. The intensity along the normal is 10-60 percent less than the peak intensity (i.e., 90-40% of the peak intensity). With typical wide emitting lenses, the brightness along the normal is made as small as possible. The present lens is designed to produce a substantially uniform intensity upon a flat output surface of a backlight box (FIG. 4) where a majority of light emitted from the backlight is due to direct illumination by the LED rather than through reflected light in the backlight box. In one embodiment, the intensity along the normal is 50-70% of the peak intensity.

The dimensions of the concave lens are selected to optimally illuminate a flat surface at a particular distance from the LED die. Any change to the lens thickness, width, or curvature will typically change the angle of peak intensity.

FIG. 4 is a cross-sectional view of a backlight 40 containing an array of encapsulated LEDs similar to LED 20 or 28 in FIGS. 1 and 2. Selected light rays 41 are also shown. The light rays 41 may or may not have the same brightness levels, and the direct light from a plurality of LEDs overlap on the top output surface of the backlight 40 to create a substantially uniform brightness profile across the output surface. Each LED shown in the backlight 40 may output white light using phosphor conversion, or the LEDs may output different colors. If the LEDs form an array of red, green, and blue LEDs, the light rays overlap to create substantially uniform white light across the output surface of the backlight 40. Since LED dies of different types may have different emission profiles and different brightness levels, the lenses for one type of LED may be different from the lenses for a different type of LED to achieve the optimal overlap and color contribution necessary for a substantially uniform white point across the backlight output surface.

Backlight 40 is formed of reflective inner surfaces 42, a top diffuser sheet 44 (e.g., a roughened plastic sheet), and one or more brightness enhancement films (BEFs) 46. The diffuser sheet 44 and each BEF 46 may be very thin (less than 1 mm). The diffuser sheet 44 improves the brightness uniformity across the surface of the backlight. The BEFs 46 may be formed by a micro-prism pattern in a plastic sheet that redirects light within a narrow angle toward the viewer. A liquid crystal display 48 overlies the backlight 40 and, essentially, has a controllable shutter at each pixel location for the RGB pixels for displaying a color image. If the backlight 40 emits white light (containing RGB components), a red, green, or blue filter at the corresponding RGB pixel locations only passes the intensity-modulated red, green, or blue component.

The lens shape, the spacing between LEDs, and the distance to the top of the backlight are selected so that the emissions from adjacent LEDs merge to form a substantially uniform illumination over the backlight top surface. Since the light emitted through the center of the lens 26 normal to the LED surface travels the least distance to the backlight top surface, that light has the least spreading, while the peak intensity light emitted at a 35-65 degree angle travels further to impinge upon the top surface of the backlight and thus spreads out more before impinging on the backlight top surface. The combination of the intensity profile (FIG. 3B) and the different distances the light rays travel to impinge on the top surface of the backlight results in the intensity pattern across the top surface of the backlight to be substantially uniform within a defined area.

FIG. 5A is a top down view of a backlight 50 containing only four LEDs with circular lenses 26. It is assumed in this simplified embodiment that each LED outputs the same color light (e.g., white light) so mixing of different colors of LED light is not a concern. The circles 52 represent an equi-brightness pattern of each LED impinging on the diffuser sheet 44 of the backlight. FIG. 5B is a top down view of LED 20 of FIG. 1 comprising a single LED die 22 with a circular lens 26. As seen in FIG. 5A, adjacent circular emission patterns may overlap, abut, or be slightly separated; however, the resulting illumination pattern at the output of the backlight appears fairly uniform due to the smoothly varying emission pattern and the diffuser sheet 44.

To further improve the brightness uniformity, each lens may have a generally rectangular shape, as shown in the top down view of a single LED 56 with lens 58 in FIG. 6B. The equi-brightness emission from each LED impinging on a diffuser sheet is shown by the rectangles 60 in FIG. 6A. The backlight 62 in FIG. 6B has improved brightness uniformity since the overlap of the rectangular emissions from the individual LEDs is more consistent over the surface of the backlight.

In one embodiment, the thickness of a lens 26 is 0.5 to 1 mm, and the width of the lens is about 2-3 mm, given that an LED die is about 1 mm×1 mm. The lens dimensions may be different depending on the LED type, the backlight configuration, the pitch of the LEDs, and other factors. In one embodiment, the distance between the top of the lens 26 and the backlight diffuser sheet 44 is 1-3 cm. In one embodiment, the total thickness of the backlight box is 3.5 cm. The optimum pitch of the LEDs on the backlight base, the number of LEDs, and the size of the lens may be determined empirically depending on the required size of the backlight and the required brightness of the backlight emission.

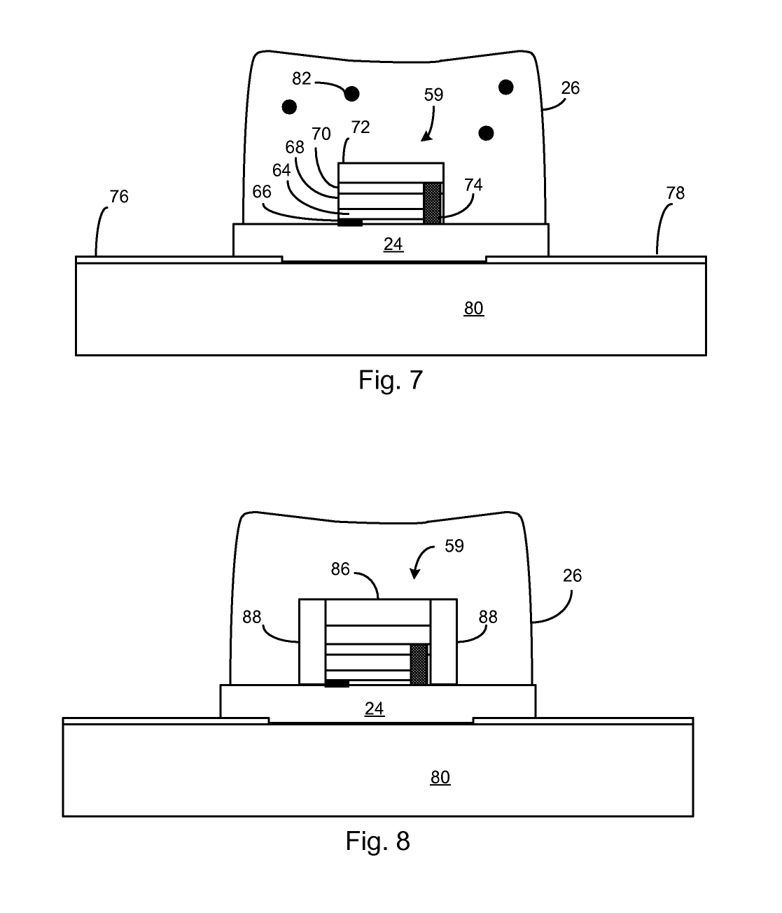

To create white light from each LED, the LED die may emit blue light, and phosphor particles energized by the blue light generate red, green, and/or yellow components that combine with the blue light to create white light, as illustrated in FIG. 7.

FIG. 7 is a simplified close-up view of one embodiment of a flip-chip LED die 59 on a submount 24, where the submount 24 is formed of any suitable material, such as a ceramic or silicon. The LED die 59 has a bottom p-contact layer 64, a p-metal contact 66, p-type layers 68, a light emitting active layer 70, n-type layers 72, and an n-metal contact 74 contacting the n-type layers 72. Metal pads on submount 24 are directly metal-bonded to contacts 66 and 74. Vias through submount 24 terminate in metal pads on the bottom surface of submount 24, which are bonded to the metal leads 76 and 78 on a circuit board 80. The metal leads 76 and 78 are connected to other LEDs or to a power supply. Circuit board 80 may be a metal plate (e.g., aluminum) with the metal leads 76 and 78 overlying an insulating layer. The molded lens 26 encapsulates the LED die 59. The board 80 may be a strip, and identical strips may be arranged in a desired pattern on the base surface of a backlight box of any size.

In FIG. 7, phosphor particles 82 are dispersed in the liquid lens material before the lens material is dispensed in the mold. A YAG phosphor generates a yellow-green light when energized by blue light and may be suitable for producing white light. Red phosphor may be added to create a warmer white light.

In FIG. 8, the phosphor is formed either as a preformed sheet 86 that is affixed over the LED die 59, or the entire surface of the LED die 59 is coated with phosphor 86/88 by, for example, electrophoresis or any other coating technique.

In another embodiment, the LED die may be a non-flip-chip die, with a wire connecting the top n-layers to a metal pad on the submount. The lens then also encapsulates the wire.

While particular embodiments of the present invention have been shown and described, it will be obvious to those skilled in the art that changes and modifications may be made without departing from this invention in its broader aspects and, therefore, the appended claims are to encompass within their scope all such changes and modifications as fall within the true spirit and scope of this invention.

What is claimed is:

1. A light emitting structure comprising:
a light emitting diode (LED) die having a center axis substantially normal to a primary light emitting surface of the LED die; and
a lens positioned over the LED die, the lens having a convex portion around the center axis of the LED die with a smooth transition between an edge of the convex portion and sidewalls of the lens, the lens refracting light emitted by the LED die to cause a peak intensity to occur within 35-65 degrees off the center axis and an intensity along the center axis to be between 40% and 90% of the peak intensity.

2. The structure of claim 1 wherein light emitted from the lens creates a brightness profile at a certain distance from the lens, the brightness profile not having any sharp transitions between the center axis and an angle of peak intensity.

3. The structure of claim 1 wherein the intensity along the center axis is between 50% and 70% of the peak intensity.

4. The structure of claim 1 wherein the lens encapsulates the LED die.

5. The structure of claim 1 wherein the lens is molded directly over the LED die and encapsulates the LED die.

6. The structure of claim 1 wherein the lens is silicone.

7. The structure of claim 1 further comprising a submount on which the LED die is mounted, wherein the lens encapsulates the LED die by forming a seal around the submount.

8. The structure of claim 1 further comprising a reflective backlight box housing the LED die and lens, a light emission from the lens on a portion of a light output surface of the backlight box forming a substantially uniform brightness profile.

9. The structure of claim 1 further comprising a backlight box, housing the LED die and lens, and a liquid crystal display panel optically coupled to the backlight box for being illuminated by the backlight box.

10. The structure of claim 1 wherein the LED die is a first LED die, and the lens is a first lens, the structure further comprising a reflective backlight box housing the first LED die and the first lens, the backlight box also housing a plurality of LED dies with associated lenses, light emissions from the first lens and associated lenses merging on a light output surface of the backlight box to form a substantially uniform brightness profile across a portion of a surface area of the light output surface of the backlight box.

11. The structure of claim 10 wherein the first lens is different from the associated lenses.

12. The structure of claim 10 wherein the first LED die outputs a first color, and the plurality of LED dies output different colors.

13. The structure of claim 10 wherein light directly impinging on the light output surface of the backlight box from the first LED and plurality of LEDs generates greater than 50% of all light emitted by the backlight box.

14. The structure of claim 10 wherein the first lens is substantially circular.

15. The structure of claim 10 wherein the first lens is substantially rectangular.

16. The structure of claim 1 wherein the first lens is substantially circular.

17. The structure of claim 1 wherein the first lens is substantially rectangular.

18. The structure of claim 1 further comprising phosphor dispersed in the lens to create white light when combined with light directly emitted by the LED die.

19. The structure of claim 1 further comprising phosphor overlying at least one surface of the LED die to create white light when combined with light directly emitted by the LED die.

20. The structure of claim 1 wherein the lens has a thickness less than 2 mm.

21. The structure of claim 1 wherein the lens has a width less than 3 mm.
